(19) United States
(12) Patent Application Publication
(10) Pub. No.: US 2025/0132219 A1
(43) Pub. Date: Apr. 24, 2025

(54) SEMICONDUCTOR DEVICE, METHOD FOR MANUFACTURING SEMICONDUCTOR DEVICE, AND THERMALLY CONDUCTIVE SHEET FOR SEMICONDUCTOR DEVICE

(71) Applicant: Resonac Corporation, Minato-ku, Tokyo (JP)

(72) Inventors: Kazue HIRANO, Minato-ku, Tokyo (JP); Masaya TOBA, Minato-ku, Tokyo (JP)

(21) Appl. No.: 18/834,229

(22) PCT Filed: Feb. 2, 2022
(86) PCT No.: PCT/JP2022/004086

§ 371 Date: Nov. 18, 2024

(51) Int. Cl. H01L 23/367; H01L 23/00; H01L 23/373; H05K 1/18

(52) U.S. Cl. CPC H01L 23/3672; H01L 23/3736; H01L 24/08; H01L 24/16; H01L 24/32; H01L 24/73; H01L 2224/08225; H01L 2224/16227; H01L 2224/16237; H01L 2224/32225; H01L 2224/73204; H01L 2924/1815; H05K 1/181

(57) ABSTRACT

A semiconductor device including: a semiconductor component including a semiconductor chip; a heat dissipation member; and a thermally conductive sheet interposed between the semiconductor component and the heat dissipation member. The thermally conductive sheet includes a resin sheet having a through-hole, and a thermally conductive portion filled in the through-hole. The thermally conductive sheet and the heat dissipation member may be provided on a side opposite to a circuit surface of the semiconductor chip. The heat dissipation member may be a heat spreader or a heat sink.

### TECHNICAL FIELD

The present disclosure relates to a semiconductor device, a method for manufacturing the semiconductor device, and a thermally conductive sheet for the semiconductor device.

### BACKGROUND ART

In order to conduct heat generated by a heat generation body including a semiconductor element to a heat dissipation body such as a heat sink and a heat spreader, a thermally conductive adhesive material may be provided between the heat generation body and the heat dissipation body in a semiconductor device. For example, Patent Literature 1 discloses a sheet-shaped heat dissipation member containing a silicone resin and a thermally conductive powder. Patent Literature 2 discloses a thermally conductive adhesive material consisting of a material in which a filler containing a thermally conductive material is dispersed in a resin. In a case of the materials, heat is transferred by contact of the thermally conductive powder or the filler.

### CITATION LIST

### Patent Literature

Patent Literature 1: Japanese Unexamined Patent Publication No. 2007-059877
Patent Literature 2: Japanese Unexamined Patent Publication No. 2007-189154

### SUMMARY OF INVENTION

### Technical Problem

The present disclosure relates to a semiconductor device capable of dissipating heat from a semiconductor component with high efficiency.

### Solution to Problem

An aspect of the present disclosure relates to a semiconductor device comprising: a semiconductor component comprising a semiconductor chip; a heat dissipation member; and a thermally conductive sheet interposed between the semiconductor chip and the heat dissipation member. The thermally conductive sheet comprises a resin sheet having a through-hole, and a thermally conductive portion filled in the through-hole.

Another aspect of the present disclosure relates to a method for manufacturing a semiconductor device. The method includes: providing a thermally conductive sheet on a semiconductor component including a semiconductor chip, wherein the thermally conductive sheet comprises a resin sheet having a through-hole and a thermally conductive portion filled in the through-hole; and bonding a heat dissipation member onto the thermally conductive sheet on a heat generation member.

Still another aspect of the present disclosure relates to a method for manufacturing a semiconductor device. The method includes: providing a thermally conductive sheet on a heat dissipation member, wherein the thermally conductive sheet comprises a resin sheet having a through-hole and a thermally conductive portion filled in the through-hole; and bonding a semiconductor component comprising a semiconductor chip onto the thermally conductive sheet on the heat dissipation member.

Still another aspect of the present disclosure relates to a thermally conductive sheet for a semiconductor device. The thermally conductive sheet comprises: a resin sheet having a through-hole; and a thermally conductive portion filled in the through-hole. In other words, still another aspect of the present disclosure relates to usage or application of the thermally conductive sheet comprising a resin sheet having a through-hole and a thermally conductive portion filled in the through-hole, for manufacturing a semiconductor device.

### Advantageous Effects of Invention

A semiconductor device capable of dissipating heat from a semiconductor chip with high efficiency can be provided. In a case of a thermally conductive bonding material containing a thermally conductive powder or filler, thermal conductivity may deteriorate due to settling of the powder or the filler, or the like, but in a case of the thermally conductive sheet according to the present disclosure, efficient thermal conduction in a thickness direction can be more reliably secured.

### BRIEF DESCRIPTION OF DRAWINGS

FIG. 1 is a cross-sectional view illustrating an example of a semiconductor device.

FIG. 2 is a cross-sectional view illustrating an example of a cross-sectional shape of a thermally conductive portion.

FIG. 3 is a plan view illustrating an example of a thermally conductive sheet.

FIG. 4 is a process view illustrating an example of a method for manufacturing a semiconductor device.

FIG. 5 is a perspective view illustrating an example of the thermally conductive sheet.

FIG. 6 is a process view illustrating an example of a method for manufacturing a semiconductor device.

### DESCRIPTION OF EMBODIMENTS

Hereinafter, examples of the present disclosure will be described in detail with reference to the accompanying drawings. In the following description, the same reference numeral will be given to the same or equivalent part, and redundant description will be omitted. Positional relationships such as up, down, left, and right are based on positional relationships shown in the drawings unless otherwise stated. Dimensional ratios of the drawings are not limited to ratios shown in the drawings. Terminologies such as “left”, “right”, “front surface”, “rear surface”, “up”, “down”, “upward”, and “downward” do not necessarily represent that their relative positions do not vary. A terminology such as “layer” includes not only a structure with a shape formed on an entire surface when being observed in a plan view, but also a structure with a shape formed only at a part of the surface.

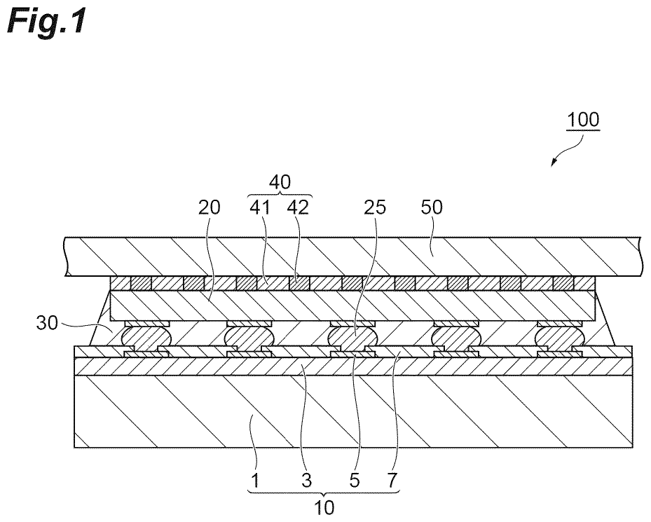

FIG. 1 is a cross-sectional view illustrating an example of a semiconductor device. A semiconductor device 100 shown in FIG. 1 includes a circuit board 10, a semiconductor component 20 that is mounted on the circuit board 10, a solder bump 25 that is interposed between the circuit board 10 and the semiconductor component 20 for electrical connection thereof, an insulating resin layer 30 that is filled between the semiconductor component 20 and the circuit board 10, a heat dissipation member 50 that is provided in the vicinity of the semiconductor component 20, and a thermally conductive sheet 40 that is interposed between the semiconductor component 20 and the heat dissipation member 50. The semiconductor component 20 may be a single semiconductor chip, or may be a chiplet or a memory cube including a plurality of semiconductor chips. A plurality of the semiconductor components 20 may be mounted on one piece of the circuit board 10.

The thermally conductive sheet 40 includes a resin sheet 41 having a plurality of through-holes, and a thermally conductive portion 42 that is filled in each of the through-holes. The thermally conductive portion 42 is exposed from both surfaces of the thermally conductive sheet 40, and is thermally connected to the semiconductor component 20 and the heat dissipation member 50. Heat that is generated when the semiconductor component 20 operates is efficiently transferred to the heat dissipation member 50 mainly through the thermally conductive portion 42 of the thermally conductive sheet 40. The thermally conductive sheet 40 is provided to cover a part or the entirety of a main surface of the semiconductor component 20 on the heat dissipation member 50 side. The main surface of the semiconductor component 20 covered by the thermally conductive sheet 40 may be a rear surface on a side opposite to a circuit surface of a semiconductor chip. In other words, the thermally conductive sheet 40 and the heat dissipation member 50 may be provided on a side opposite to the circuit surface of the semiconductor chip constituting the semiconductor component 20.

The thickness of the thermally conductive sheet 40 (or the resin sheet 41) may be 10 μm or more and 500 μm or less or 15 μm or more and 30 μm or less. The thermally conductive sheet 40 having an appropriate thickness allows particularly efficient thermal conduction to be performed, and is less susceptible to breakage.

For example, the resin sheet 41 may contain a thermoplastic resin, a photosensitive resin, or a thermosetting resin. The resin sheet 41 may be a cured product of a thermosetting resin composition.

The resin sheet 41 may contain a filler. The filler may be an inorganic filler from the viewpoint of thermal conduction efficiency. Examples of the inorganic filler include alumina, silicon nitride, silica, copper, aluminium, silver, talc, mica, zinc, magnesium oxide, boron nitride, aluminium nitride, carbon black, graphite, and carbon fiber. The content of the filler may be 30% by mass or more and 90% by mass or less on the basis of the mass of the resin sheet 41.

The resin sheet 41 may have relatively low thermal conductivity. The thermal conductivity of the resin sheet 41 may be 0.1 W/m·K or more and 10 W/m·K or less.

The thermally conductive portion 42 has thermal conductivity higher than the thermal conductivity of the resin sheet 41. The thermal conductivity of the thermally conductive portion 42 may be larger than thermal conductivity of the heat dissipation member 50. The thermal conductivity of the thermally conductive portion 42 may be 20 W/m·K or more and 90 W/m·K or less.

The thermally conductive portion 42 may contain a metal. Examples of the metal constituting the thermally conductive portion 42 include copper, silver, and aluminium. From the viewpoint of economic efficiency, the thermally conductive portion 42 may contain copper, and more particularly include copper plating. The thermally conductive portion 42 may be a metal layer formed from metal paste.

For example, a maximum width of the thermally conductive portion 42 may be 10 μm or more and 1000 μm or less. The maximum width stated here represents a maximum value of a width of a cross-section orthogonal to a thickness direction of the thermally conductive sheet 40.

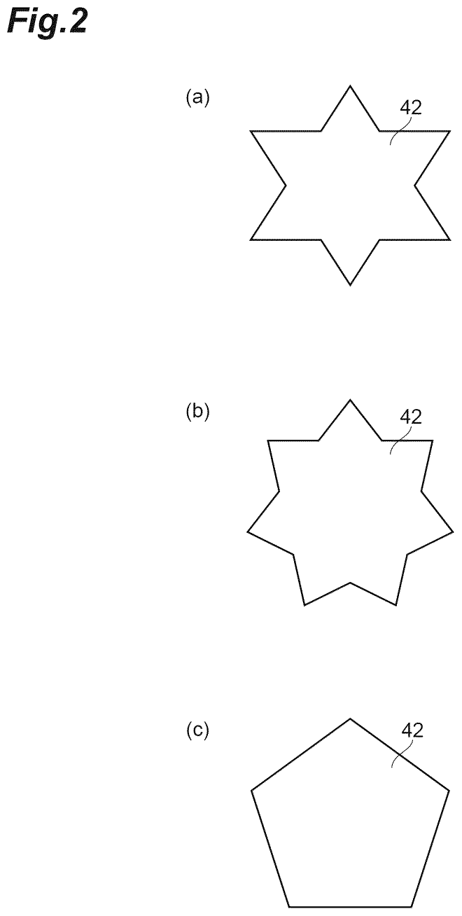

The cross-section of the thermally conductive portion 42 (cross-section orthogonal to the thickness direction of the thermally conductive sheet 40) may have a circular shape, a polygonal shape, or any other shapes. Particularly, from the viewpoint of adhesiveness between the thermally conductive portion 42 and the resin sheet 41, the thermally conductive portion 42 may have a polygonal cross-section shape. FIG. 2 is a cross-sectional view illustrating several examples of the cross-sectional shape of the thermally conductive portion 42. In FIG. 2, (a) and (b) are examples of a non-convex polygonal cross-section shape having an outer periphery that forms unevenness, and (c) is an example of a convex polygonal cross-section shape.

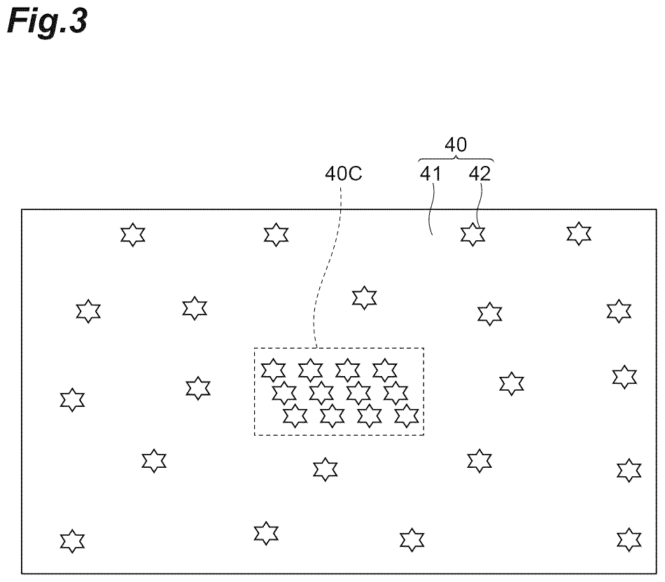

A plurality of the thermally conductive portions 42 may be uniformly arranged over the entirety of a thermally conductive sheet, or may be arranged biasedly in a certain region. FIG. 3 is a plan view illustrating an example of a thermally conductive sheet in which the thermally conductive portions 42 are arranged biasedly. In a case of the thermally conductive sheet 40 shown in FIG. 3, the thermally conductive portions 42 are arranged biasedly at a central portion 40C of the thermally conductive sheet 40. For example, a ratio of a total volume of the plurality of thermally conductive portions 42 may be 60% or more and 70% or less at the central portion 40C on the basis of the volume of the thermally conductive sheet 40, and 30% or more and 40% or less in a region other than the central portion 40C. Since a relatively large stress is applied to a region of an end portion of the thermally conductive sheet 40, when the thermally conductive portions 42 are arranged biasedly in the central portion 40C of the thermally conductive sheet 40, thermal conduction can be made more efficient while maintaining high reliability.

The heat dissipation member 50 may be a heat spreader or a heat sink. The heat dissipation member 50 may be a lid that covers the entirety of the semiconductor component 20. A material that constitutes the heat dissipation member 50 can be selected from typical materials which can be used as the heat spreader or the heat sink. For example, an area of a main surface of the heat dissipation member 50 may be the same as an area of a main surface of the thermally conductive sheet 40, or may be larger than the area of the main surface of the thermally conductive sheet 40.

The circuit board 10 includes a base material 1, a wiring portion 3 provided on the base material 1, an electrode pad 5 provided on a surface of the wiring portion 3 which is opposite to the base material 1, and a surface insulating resin layer 7 having an opening through which the central portion of the electrode pad 5 is exposed. The circuit board 10 may be a circuit board including an interposer.

For example, the base material 1 may be a silicon substrate, a glass substrate, a stainless substrate, or a glass cloth, or may be semiconductor package including a semiconductor chip and a sealing resin layer that seals the semiconductor chip.

The thickness of the base material 1 may be, for example, 0.2 mm or more and 2.0 mm or less. A base material having a thickness of 0.2 mm or more is likely to have satisfactory handling property. A base material having a thickness of 2.0 mm or less is advantageous from the viewpoint of the manufacturing cost. The base material 1 may be a wafer having a circular main surface, or a panel having a rectangular main surface. For example, the base material 1 may be a wafer having a circular main surface with a diameter of 200 mm or more and 450 mm or less, or a panel having a rectangular main surface with a width of 300 mm or more and 700 mm or less.

The wiring portion 3 may include an insulating resin layer and a wiring layer provided in the insulating resin layer. The wiring portion 3 may have a multi-layer wiring structure including two or more wiring layers.

The electrode pad 5 may be a copper pad containing copper. The thickness of the electrode pad 5 may be 1 μm or more and 20 μm or less, 3 μm or more and 15 μm or less, or 5 μm or more and 15 μm or less.

For example, the surface insulating resin layer 7 can be formed from a resist material that is typically used to form a solder resist. The opening of the surface insulating resin layer 7 can be formed by, for example, laser ablation, photolithography (exposure and development), or imprint. In a case of the photolithography, a photosensitive resist material is used.

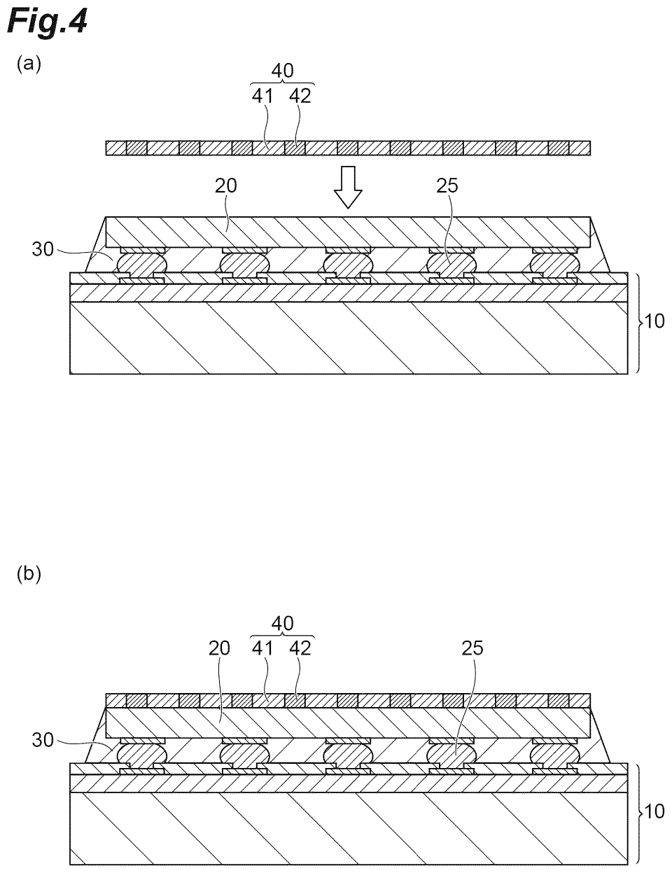

FIG. 4 is a process view illustrating an example of a method for manufacturing a semiconductor device. The method shown in FIG. 4 includes a process of mounting the semiconductor component 20 on the circuit board 10, a process of forming the insulating resin layer 30 that is filled between the semiconductor component 20 and the circuit board 10, a process of providing the thermally conductive sheet 40 on the main surface of the semiconductor component 20 which is opposite to the circuit board 10, and a process of bonding the heat dissipation member 50 onto the thermally conductive sheet 40 on the semiconductor component 20.

The circuit board 10 can be prepared by a typical method understood by those skilled in the art. The process of mounting the semiconductor component 20 on the circuit board 10, and the process of forming the insulating resin layer 30 filled between the semiconductor component 20 and the circuit board 10 can be performed by a typical method.

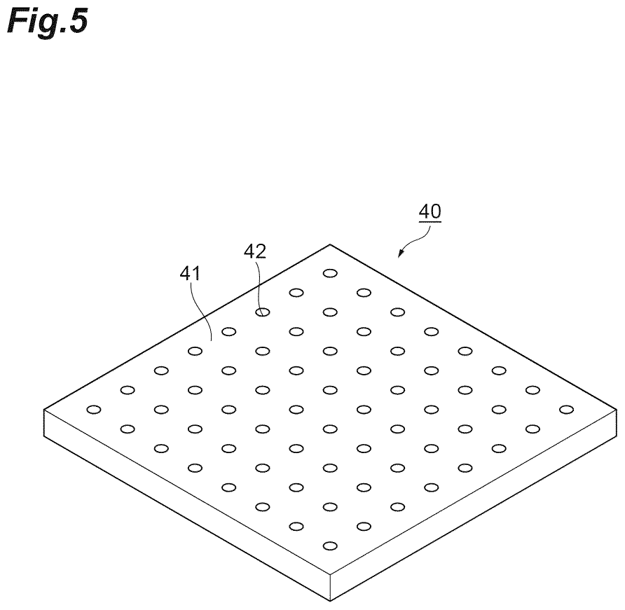

In a case of FIG. 4, the thermally conductive sheet 40 prepared in advance is bonded to the semiconductor component 20. FIG. 5 is a perspective view illustrating an example of the thermally conductive sheet 40 prepared in advance. The thermally conductive sheet 40 can be bonded to the semiconductor component 20 by pressing the thermally conductive sheet 40 to the semiconductor component 20. The pressing may be accompanied with heating.

In the thermally conductive sheet 40 at the time of being bonded to the semiconductor component 20, the resin sheet 41 may be a sheet formed from an uncured or semi-cured thermosetting resin composition. In this case, after the semiconductor component 20 is bonded to the thermally conductive sheet 40, the thermosetting resin composition that constitutes the resin sheet 41 may be cured. After the resin sheet 41 having a through-hole is formed on the semiconductor component 20, the thermally conductive portion 42 that fills the through-hole may be formed. For example, the through-hole (via) of the resin sheet 41 may be formed by a laser, photolithography, or a mold. For example, the thermally conductive portion 42 may be formed by electrolytic plating or printing of metal paste.

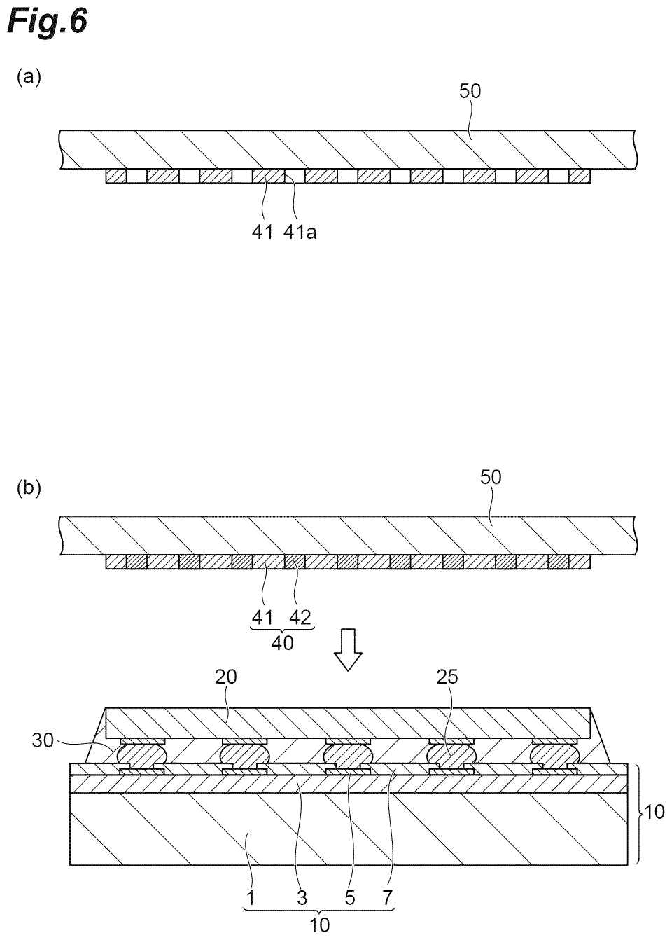

FIG. 6 is a process view illustrating another example of the method for manufacturing the semiconductor device. The method shown in FIG. 6 includes a process of forming the resin sheet 41 having a through-hole 41a on the heat dissipation member 50, a process of forming the thermally conductive portion 42 filled in the through-hole 41a, thereby providing the thermally conductive sheet 40 on the heat dissipation member 50, and a process of bonding the semiconductor component 20 mounted on the circuit board 10 to the thermally conductive sheet 40 on the heat dissipation member 50. The thermally conductive sheet 40 prepared in advance may be bonded to the heat dissipation member 50.

### REFERENCE SIGNS LIST

1: base material, 3: wiring portion, 5: electrode pad, 7: surface insulating resin layer, 10: circuit board, 20: semiconductor component, 25: solder bump, 40: thermally conductive sheet, 41: resin sheet, 42: thermally conductive portion, 100: semiconductor device.

1. A semiconductor device, comprising:
a semiconductor component comprising a semiconductor chip;
a heat dissipation member; and
a thermally conductive sheet interposed between the semiconductor component and the heat dissipation member,
wherein the thermally conductive sheet comprises a resin sheet having a through-hole, and a thermally conductive portion filled in the through-hole.

2. The semiconductor device according to claim 1,
wherein the thermally conductive sheet and the heat dissipation member are provided on a side opposite to a circuit surface of the semiconductor chip.

3. The semiconductor device according to claim 1,
wherein the thermally conductive portion has a polygonal cross-sectional shape.

4. The semiconductor device according to claim 1,
wherein thermal conductivity of the thermally conductive portion is larger than thermal conductivity of the heat dissipation member.

5. The semiconductor device according to claim 1,
wherein the thermally conductive portion comprises a metal.

6. The semiconductor device according to claim 1,
wherein the heat dissipation member is a heat spreader or a heat sink.

7. A method for manufacturing a semiconductor device, the method comprising:
providing a thermally conductive sheet on a semiconductor component comprising a semiconductor chip, the thermally conductive sheet comprising a resin sheet having a through-hole and a thermally conductive portion filled in the through-hole; and
bonding a heat dissipation member onto the thermally conductive sheet on the semiconductor component.

8. A method for manufacturing a semiconductor device, the method comprising:
providing a thermally conductive sheet on a heat dissipation member, the thermally conductive sheet comprising a resin sheet having a through-hole and a thermally conductive portion filled in the through-hole; and
bonding a semiconductor component comprising a semiconductor chip onto the thermally conductive sheet on the heat dissipation member.

9. A thermally conductive sheet for a semiconductor device, comprising:
a resin sheet having a through-hole; and
a thermally conductive portion filled in the through-hole.

10. (canceled)

11. The thermally conductive sheet according to claim 9,
wherein the thermally conductive portion has a polygonal cross-sectional shape.

12. The thermally conductive sheet according to claim 9,
wherein the thermally conductive portion contains a metal.
